(19) United States
(12) Patent Application Publication
(10) Pub. No.: US 2013/0233598 A1
(43) Pub. Date: Sep. 12, 2013

(54) FLEXIBLE FILM CARRIER TO INCREASE INTERCONNECT DENSITY OF MODULES AND METHODS THEREOF

(71) Applicant: Benjamin V. Fasano, New Windsor, NY (US)

(72) Inventor: Benjamin V. Fasano, New Windsor, NY (US)

(73) Assignee: INTERNATIONAL BUSINESS MACHINES CORPORATION, Armonk, NY (US)

(21) Appl. No.: 13/414,743

(22) Filed: Mar. 8, 2012

(51) Int. Cl. H05K 1/00; H05K 3/30

(52) U.S. Cl. 174/254; 174/250; 29/837

(57) ABSTRACT

A flexible film carrier and methods of manufacture, and more particularly, methods and structures to increase interconnect density of modules onto circuit boards is discloses. The structure includes a substrate comprising a plurality of holes and a plurality of contacts having a pitch corresponding to a pitch of I/O connections of a laminate. The structure further includes at least one type of connection provided on the substrate and which is positioned so as to avoid interference with a connection of the laminate to a circuit board. The structure further includes wiring electrically connecting the plurality of contacts to the at least one type of connection.

### FIELD OF THE INVENTION

The invention relates to a flexible film carrier and methods of manufacture, and more particularly, to methods and structures to increase interconnect density of modules onto circuit boards.

### BACKGROUND

Laminates used for integrated circuit packaging are typically large enough to accommodate all top surface metallurgy and bottom surface metallurgy I/O connections. For example, top surface metallurgy has an interconnect density provided by finer C4 solder pitch. In fact, chip C4 pitch can be contained within manufacturing capabilities of laminate (chip carrier) suppliers to below 150 um. The bottom surface metallurgy I/O connections can also have a pitch of less than 1 mm, with Land Grid Arrays (LGA) meeting the same requirements of less than 1 mm, and more on the order of about 0.75 mm.

However, many restrictions exist on printed circuit boards, which make it impractical to have the same fine pitch as the bottom surface metallurgy I/O connections of the laminate or the LGA. For example, the finest reliable pitch of a printed circuit board is currently about 1 mm, which limits a total of the I/O connections for a 50 mm square laminate to less than 2,500 I/O connections. These restrictions are due to the complexities involved in manufacturing a printed circuit board, as well as the need for increased die functionality and shielding requirements that require higher I/O connection counts. Thus, to accommodate these restrictions, laminates are usually much bigger than needed to provide bottom surface metallurgy I/O connection counts for power/ground and signal delivery and shielding. However, this is expensive and consumes printed circuit board area, driving to larger printed circuit boards than desired.

Accordingly, there exists a need in the art to overcome the deficiencies and limitations described hereinabove.

### SUMMARY

In a first aspect of the invention, a structure comprises a substrate comprising a plurality of holes and a plurality of contacts having a pitch corresponding to a pitch of I/O connections of a laminate. The structure further comprises at least one type of connection provided on the substrate and which is positioned so as to avoid interference with a connection of the laminate to a circuit board. The structure further comprises wiring electrically connecting the plurality of contacts to the at least one type of connection.

In another aspect of the invention, a package comprises a substrate, a laminate and a board. The substrate comprises an array of holes and a contacts, one or more connections, and wiring electrically connecting the contacts to the one or more connections. The laminate comprises I/O connections which have a one to one correspondence with the array of holes and contacts. The board comprises I/O connections which correspond with the holes of the substrate.

In another aspect of the invention, a method of forming a flexible film carrier comprises: forming a flexible substrate; forming a plurality of holes in the flexible substrate that match connections on a board and selected connections on a corresponding laminate; forming a plurality of contacts on the flexible substrate that match to other selected connections on the laminate; forming at least one connection on the substrate; and forming a plurality of wires in or on the substrate, connecting the at least one connection to the plurality of contacts. The plurality of holes and the plurality of contacts are formed in an array having a pitch corresponding to a pitch of I/O connections of the corresponding laminate.

In another aspect of the invention, a design structure tangibly embodied in a machine readable storage medium for designing, manufacturing, or testing an integrated circuit is provided. The design structure comprises the structures of the present invention. In further embodiments, a hardware description language (HDL) design structure encoded on a machine-readable data storage medium comprises elements that when processed in a computer-aided design system generates a machine-executable representation of the structures of the present invention. In still further embodiments, a method in a computer-aided design system is provided for generating a functional design model of the interconnect structures. The method comprises generating a functional representation of the structural elements of the present invention.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIG. 1 shows a flexible film carrier in accordance with aspects of the present invention;

FIG. 2 shows an alternative flexible film carrier in accordance with aspects of the present invention;

FIG. 3 shows an exploded view of a package implementing the flexible film carrier of FIG. 1, in accordance with aspects of the present invention; and

FIG. 4 shows an exploded view of a package implementing the flexible film carrier of FIG. 2, in accordance with aspects of the present invention.

### DETAILED DESCRIPTION

The invention relates to a flexible film carrier and methods of manufacture, and more particularly, to methods and structures to increase interconnect density of modules onto circuit boards. More specifically, the present invention provides a flexible film carrier positioned between, for example, a laminate and a circuit board, where the laminate has a different input/output (I/O) pitch than the circuit board. For example, in embodiments, the I/O pitch of the laminate can be less than 1 mm; whereas, the pitch on the circuit board is typically restricted to 1 mm or more due to increased complexity and costs required to manufacture circuit boards with a denser or finer pitch.

Advantageously, the flexible film carrier can be used to connect the laminate to the circuit board, even though there is a mismatch in pitch between the I/O connections between the components. In addition, by using the flexible film carrier, it is now possible to “space transform” the I/O pattern of a bottom surface metallurgy of the laminate to beyond the footprint of the laminate. That is, I/O connections of the laminate that do not match to the I/O connections of the circuit board can now be used to connect to other components, devices, etc., ordinarily beyond the reach of the laminate. In this way, the functionality of the laminate can be expanded beyond the circuit board.

In implementations, a plurality of I/O connections of the laminate can be matched to the I/O connections of the circuit board through openings of the flexible film carrier; whereas, other I/O connections of the laminate can be matched to respective contacts of the flexible firm carrier. The contacts of the flexible firm carrier can be connected to wiring which, in turn, will electrically connect the I/O connections of the laminate to solder pads, pluggable contacts, edge connectors, etc. on the flexible film carrier. In turn, the solder pads, pluggable contacts, edge connectors, etc. can connect to outside components, ordinarily outside the limits of the laminate. In this way, it is possible to expand the functionality of the package, by making breakaway connections to the laminate that are beyond THE footprint of the laminate. Accordingly, the flexible film carrier of the present invention allows many degrees of freedom for extending the wiring regions beyond the laminate metallurgy.

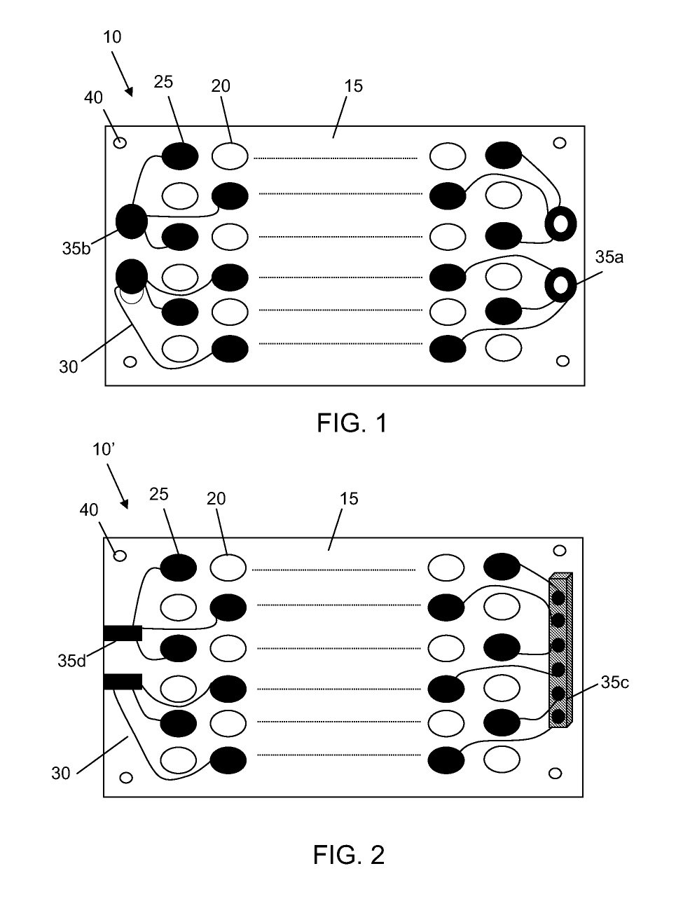

FIG. 1 shows a flexible film carrier in accordance with aspects of the present invention. More specifically, the flexible film carrier 10 comprises a substrate 15. In embodiments, the substrate 15 is a flexible substrate comprising, for example, a high temperature polymer which exhibits good dimensional stability. For example, the flexible substrate can be a polyimide material; although, it should be understood by those of skill in the art that other materials are also contemplated by the present invention. In embodiments, the substrate can be about 2-4 mils thick, but can vary over its cross section.

The substrate 15 includes a pattern of holes 20 and contacts 25. In embodiments, the pattern of holes 20 and contacts 25 can match an I/O pattern of a laminate (shown in FIGS. 4 and 5). In further embodiments, the pattern of the holes 20 will match an I/O pattern of the circuit board (shown in FIGS. 4 and 5). For example, the pattern of holes 20 and contacts 25 can have a pitch of less than 1 mm. In embodiments, the pattern of holes 20 and contacts 25 are provided in an alternating fashion; although other patterns are also contemplated by the present invention depending on the patterns on the laminate and/or circuit board and/or other design criteria of the packaged structure.

Still referring to FIG. 1, the contacts 25 can be any appropriate metallization. For example, the contacts 25 can be copper, aluminum, or other metal or metal alloy known to be used for contacts. In embodiments, the contacts 25 can be formed using any conventional additive or subtractive processes such as, for example, metal deposition and etching processes. The deposition process can be, for example, a conventional chemical vapor deposition process.

On the other hand, the holes 20 can be formed using conventional photolithography and etching processes. For example, a mask can be formed on the substrate 15, and exposed to light to form patterns (openings), which correspond with the soon to be formed openings 20 in the substrate 15. Thereafter, a conventional etching process, e.g., reactive ion etch (RIE), can be performed to form the openings 20. Any mask material that remains on the substrate 15 can be removed using conventional removal processes, e.g., oxygen ashing processes. Alternatively, the openings 20 can be formed using conventional mechanical processes. The substrate 15 also includes a plurality of alignment holes 40, which can be formed in the same or similar manner as the openings 20, in the same processes or different processes.

In embodiments, wirings 30 are also formed in or on the substrate 15. In embodiments, the wirings 30 can be formed using any conventional additive or subtractive processes, known to those of skill in the art. The wirings 30 may be, for example, aluminum, copper or other metal or metal alloy. The wirings 30 electrically connect the contacts 30 to solder pads 35a and/or other types of surface pads 35b, positioned on ends of the substrate 15. In embodiments, the solder pads 35a and/or other types of surface pads 35b can be positioned at other locations on the substrate 15, beyond the footprint of the laminate so as to not interfere with connections between the laminate and the circuit board. The solder pads 35a and/or other types of surface pads 35b can connect to other components remote from the laminate, including to solder connections on the circuit board.

FIG. 2 shows an alternative flexible film carrier in accordance with aspects of the present invention. In FIG. 2, the flexible film carrier 10′ includes different connections 35c and 35d. More specifically, the connection 35c is a pluggable connector and the connection 35d comprises edge connector pads. It should be understood that any combination of connections can be provided on the flexible film carrier, including any combination shown in FIGS. 1 and 2. As in the embodiment shown in FIG. 1, the wirings 30 electrically connect the contacts 30 to the different connections 35c, 35d, positioned on ends of the substrate 15. In embodiments, the different connections 35c and 35d can be positioned at other locations on the substrate 15, without interfering with connections between the laminate and the circuit board. As with the solder pads 35a and/or other types of surface pads 35b, the different connections 35c and 35d can connect to other components beyond the footprint of the laminate.

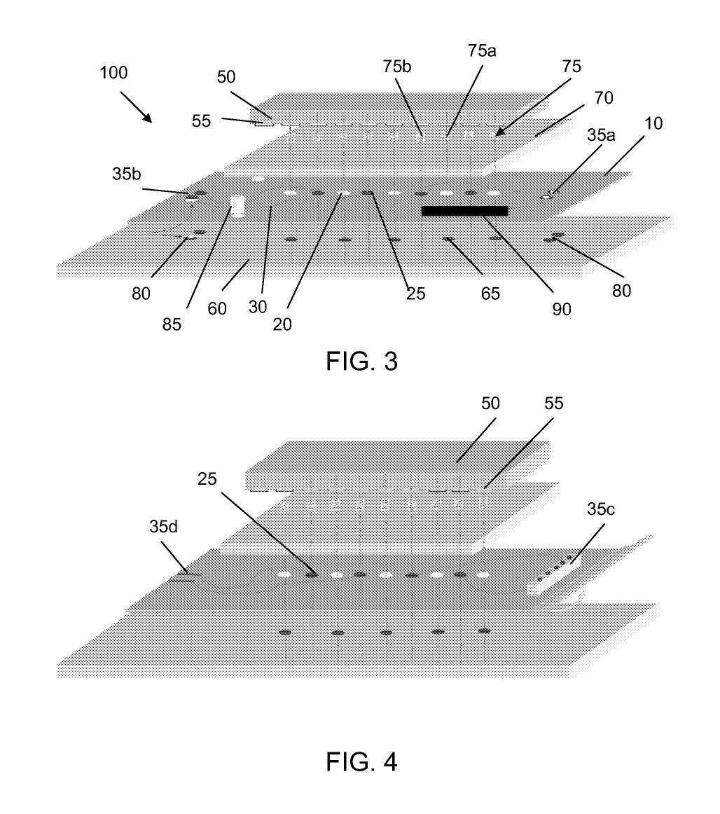

FIG. 3 shows an exploded view of a package implementing the flexible film carrier of FIG. 1, in accordance with aspects of the present invention. More specifically, the package 100 includes the flexible film carrier 10 positioned between a laminate 50 and a circuit board 60. In more specific embodiments, the flexible film carrier 10 is positioned between the laminate 50 and a Land Grid Array (LGA) interposer 70. As should be understood by those of ordinary skill in the art, the LGA interposer 70 includes a contact array 75 which corresponds in density and pitch to I/O connections 55 of the laminate 50, i.e., one to one correspondence. The contact array 75 can comprise any metal or metal alloy contact which exhibits a certain resiliency. For example, each contact in the contact array 75 can be a compressive loading connector (e.g., spring contact), which extends from a front surface to a rear surface of the LGA interposer 70. Other configurations known to those of skill in the art are also contemplated by the present invention, e.g., solder connections, conductive epoxies, etc.

As shown in FIG. 3, the circuit board 60 includes a plurality of I/O connections 65, preferably with a pitch of 1 mm or more. As should be understood by those of skill in the art, the I/O connections 65 are of a different pitch than the I/O connections 55 of the laminate 50. For example, the pitch of the I/O connections 55 of the laminate 50 can be less than a 1 mm pitch, and preferably about a 0.5 mm pitch. One or more solder pads 80 can be provided on the circuit board 60. An alignment pin 85 is also provided on the package 100, in order to align the components (e.g., to be inserted into the alignment hole 40 of the laminate 10). A retention mechanism 90, well known to those of skill in the art, is provided to retain the components.

In a packaged form, the contacts 75a of the LGA interposer 70 will contact each I/O connection 55 of the laminate 50. The contacts 75a will extend through the openings 20 of the flexible film carrier 10 and electrically connect to the contacts 65 of the circuit board 60. The remaining contacts 75b of the LGA interposer 70 will electrically connect to the contacts 25 of the flexible film carrier 10. As the contacts 25 are electrically connected to the connections 35a, 35b, through wirings, it is now possible to connect the laminate to other components, outside of the bounds of the laminate. Alternatively or in addition, the connections 35a and/or connections 35b can be connected to the solder pads 80 of the circuit board 60, to make further connections to the circuit board 60.

FIG. 4 shows an exploded view of a package implementing the flexible film carrier of FIG. 2, in accordance with aspects of the present invention. As shown in FIG. 4, the package 100′ includes the flexible film carrier 10′ with the pluggable connector 35c and edge connector pads 35d. The pluggable connector 35c and edge connector pads 35d are electrically connected to I/O connections 55 of the laminate 50 by way of the contacts 25 of the flexible film carrier 10′. The pluggable connector 35c and edge connector pads 35d can be used to connect the laminate 50 to other components.

As should be understood by those of ordinary skill in the art, the pluggable connector 35c and/or edge connector pads 35d can connect to other flexible film carriers, optical devices, controllers, memory, other printed circuit boards, or a host of other devices or connections to further use the “dead space” between components on the circuit board, if needed. These devices can be, for example, pre-attached at assembly or added later. Also, in embodiments, it should be understood that the flexible film carriers of the present invention can be provided with a stacked configuration with alternating holes and contacts, in order to provide many different contact configurations. If used in an array, additional modules and flexible carrier films can be tied together in X and Y dimensions (or Z as desired).

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure, comprising:
a substrate comprising a plurality of holes and a plurality of contacts having a pitch corresponding to a pitch of I/O connections of a laminate;
at least one type of connection provided on the substrate and which is positioned so as to avoid interference with a connection of the laminate to a circuit board; and
wiring electrically connecting the plurality of contacts to the at least one type of connection.

2. The structure of claim 1, wherein the substrate is a flexible substrate.

3. The structure of claim 1, wherein the substrate comprises a high temperature polymer.

4. The structure of claim 1, wherein the substrate comprises a polyimide material.

5. The structure of claim 1, wherein the at least one type of connection is two types of connections.

6. The structure of claim 1, wherein the at least one type of connection is positioned at an end of the substrate.

7. The structure of claim 1, wherein the plurality of holes and plurality of contacts are arranged with a pitch of less than 1 mm.

8. The structure of claim 7, wherein the plurality of holes and plurality of contacts are arranged in an alternating fashion.

9. The structure of claim 1, wherein the at least one type of connection comprises at least one of: solder pads, surface pads, a pluggable connector and edge connector pads.

10. The structure of claim 9, wherein the solder pads and surface pads are structured to be connectable to a printed circuit board.

11. The structure of claim 9, wherein the pluggable connector and the edge connector pads are structured to be connectable to external components.

12. The structure of claim 1, wherein the substrate further comprises alignment holes.

13. The structure of claim 1, further comprising:
the laminate having input/output (I/O) connections which correspond in a one to one relation with the plurality of holes and the plurality of contacts;
a printed circuit board having I/O connections which correspond with the plurality of holes of the substrate; and
a land grid array interceptor interposed between the laminate and the substrate, the land grid array having a plurality connections which match the I/O connections of the laminate.

14. A package, comprising:
a substrate comprising:
an array of holes and a contacts;
one or more connections; and
wiring electrically connecting the contacts to the one or more connections;
a laminate comprising I/O connections which have a one to one correspondence with the array of holes and contacts; and
a board comprising I/O connections which correspond with the holes of the substrate.

15. The package of claim 14, further comprising a land grid array interceptor interposed between the laminate and the substrate, the land grid array having a plurality connections which match the I/O connections of the laminate.

16. The package of claim 15, wherein the connections of the land grid array interceptor correspond to the array of holes and contacts of the substrate.

17. The package of claim 16, wherein the connections of the land grid array interceptor that match to the contacts of the substrate provide an electrical connection between selected ones of the I/O connections of the laminate and external components.

18. The package of claim 17, wherein the connections of the land grid array interceptor that match to the holes of the substrate provide an electrical connection between other selected ones of the I/O connections of the laminate and the board.

19. The structure of claim 14, wherein the one or more connections comprise at least one of solder pads, surface pads, a pluggable connector and edge connector pads, which do not interfere between connections of the laminate and the board.

20. A method of forming a flexible film carrier, comprising:
forming a flexible substrate;
forming a plurality of holes in the flexible substrate that match connections on a board and selected connections on a corresponding laminate;
forming a plurality of contacts on the flexible substrate that match to other selected connections on the laminate;
forming at least one connection on the substrate; and
forming a plurality of wires in or on the substrate, connecting the at least one connection to the plurality of contacts, wherein
the plurality of holes and the plurality of contacts are formed in an array having a pitch corresponding to a pitch of I/O connections of the corresponding laminate.
